(19) United States
(12) Patent Application Publication
(10) Pub. No.: US 2016/0164024 A1
(43) Pub. Date: Jun. 9, 2016

(54) ELECTRONIC DEVICE AND METHOD FOR MANUFACTURING SAME

(71) Applicant: KONICA MINOLTA, INC., Tokyo (JP)

(72) Inventor: Yasuhiko TAKAMUKI, Hachioji-shi, Tokyo (JP)

(21) Appl. No.: 14/906,728

(22) PCT Filed: Jul. 9, 2014
(86) PCT No.: PCT/JP2014/068361

§ 371 Date: Jan. 21, 2016

(30) Foreign Application Priority Data
Jul. 26, 2013 (JP) 2013-156145

(51) Int. Cl. H01L 51/52; H01L 51/56

(52) U.S. Cl. CPC H01L 51/5243; H01L 51/56; H01L 51/5246

(57) ABSTRACT

A purpose of the present invention is to provide an electronic device that is excellent in sealing property and resistance to repetitive bending, and a method for manufacturing the electronic device. The present invention provides an electronic device including: a substrate; an electronic element main body formed on the substrate; and a sealing substrate that is bonded to the substrate via a bonding part disposed on the surrounding of the electronic element main body to seal the electronic element main body; wherein at least one of the substrate and the sealing substrate is a gas barrier film, and the bonding part contains at least one kind selected from the group consisting of iron, cobalt, nickel, ruthenium, rhodium, palladium, osmium, iridium and platinum, and a method for manufacturing the electronic device.

### TECHNICAL FIELD

The present invention relates to an electronic device and a method for manufacturing the electronic device.

### BACKGROUND ART

Electronic devices such as organic electroluminescence elements (organic EL elements), organic solar batteries, organic transistors, inorganic electroluminescence elements and inorganic solar batteries (for example, CIGS solar batteries) are susceptible to oxygen and water content that are present in an environment of use. For example, in the case when a display or an illumination device is constituted by using an organic EL element, there is a disadvantage that the organic material itself is degenerated by oxygen or water content (including water vapor and the like), and thus the luminance decreases, and eventually, light is not emitted.

Therefore, various technologies such as a sealing method for protecting electronic devices from oxygen and water content have been suggested. Among these, a sealing technology that is excellent in properties for blocking oxygen and water content by a sealing structure obtained by attaching a sealing substrate together with a substrate with an organic EL element formed on one surface thereof, by bonding the surrounding of organic EL element with a low melting point alloy sealant is known (for example, JP 2008-546211 T (this corresponds to WO 2006/135474 A)).

### SUMMARY OF INVENTION

Meanwhile, in recent years, flexibility (resistance to repetitive bending) that enables not only a planar structure but also a curved surface structure, or easy use with repetitive deformation is required for displays and illumination devices using the above-mentioned organic EL elements.

However, the technology of JP 2008-546211 T (this corresponds to WO 2006/135474A) had problems that, in the case when a flexible substrate is bonded by using a low melting point alloy sealant, the sealability is insufficient, and that, in an embodiment of use in which the flexible substrate is bent repeatedly, stresses are concentrated on the bonded interfaces, and the interfaces are peeled, and thus the sealability is lost and the resistance to repetitive bending is poor.

Therefore, the present invention aims at providing an electronic device that is excellent in sealing property and resistance to repetitive bending, and a method for manufacturing the electronic device.

The present inventors did intensive studies so as to solve the above-mentioned problems. Consequently, they found that the above-mentioned problems are solved by an electronic device including: a substrate; an electronic element main body formed on the substrate; and a sealing substrate that is bonded to the substrate via a bonding part disposed on the surrounding of the electronic element main body to seal the electronic element main body; wherein at least one of the substrate and the sealing substrate is a gas barrier film, and the bonding part contains at least one kind selected from the group consisting of iron, cobalt, nickel, ruthenium, rhodium, palladium, osmium, iridium and platinum, and completed the present invention.

### BRIEF DESCRIPTION OF DRAWINGS

FIG. 1 is a cross-sectional schematic view showing an electronic device of an exemplary embodiment of the present invention. In FIG. 1, reference numeral 1 represents a substrate, reference numeral 2 represents a sealing substrate, reference numeral 3 represents a bonding part, reference numeral 4 represents an electronic element main body, reference numeral 5 represents a first electrode layer (anode), reference numeral 6 represents a hole transport layer, reference numeral 7 represents a light-emitting layer, reference numeral 8 represents an electron transport layer, reference numeral 9 represents an electron injection layer, reference numeral 10 represents a second electrode layer (cathode), and reference numeral 20 represents an electronic device.

FIG. 2 is a partial cross-sectional schematic view showing an electronic device of an exemplary embodiment of the present invention. In FIG. 2, reference numeral 1 represents a substrate, reference numeral 2 represents a sealing substrate, reference numeral 3 represents a bonding part, reference numeral 11 represents a silicon film, reference numeral 12 represents a silicon film, and reference numeral 13 represents a metal film.

FIG. 3 is a schematic plane view showing an electronic device according to an exemplary embodiment of the present invention. In FIG. 3, reference numeral 1 represents a substrate, reference numeral 2 represents a sealing substrate, reference numeral 3 represents a bonding part, and reference numeral 4 represents an electronic element main body.

FIG. 4 is a cross-sectional schematic view showing an example of a room-temperature bonding device in the present invention. In FIG. 4, reference numeral 1 represents a substrate, reference numeral 2 represents a sealing substrate, reference numeral 30 represents a room-temperature bonding device, reference numeral 31 represents a vacuum chamber, reference numeral 32 represents an ion gun (sputtering source), reference numeral 33 represents a target stage 1, and reference numeral 34 represents a target stage 2.

FIG. 5 is a cross-sectional schematic view showing a pressurized state for room-temperature bonding in the room-temperature bonding device in the present invention. In FIG. 5, reference numeral 1 represents a substrate, reference numeral 2 represents a sealing substrate, reference numeral 3 represents a bonding part, and reference numeral 27 represents a bonding interface.

FIG. 6 is a perspective view showing a further example of the room-temperature bonding device in the present invention. In FIG. 6, reference numeral 1 represents a substrate, reference numeral 2 represents a sealing substrate, reference numeral 32 represents an ion gun (sputtering source), reference numeral 35 represents a target, reference numerals 36a, 36b and 36c respectively represent target substrates, reference numeral 37 represents an incident ray, reference numeral 38 represents an outgoing ray (sputter particles), and reference numeral 40 represents a room-temperature bonding device.

### DESCRIPTION OF EMBODIMENTS

The embodiments for carrying out the present invention will be explained below in detail, but the present invention is not limited to these. Furthermore, in this specification, “X to Y” that represents a range means “X or more and Y or less”, and “weight” and “mass”, “% by weight” and “% by mass”, and “parts by weight” and “parts by mass” are handled as synonymous words. Furthermore, unless otherwise mentioned, the operations and the measurements of the physical properties and the like are measured under conditions of an ambient temperature (20 to 25° C.)/a relative humidity of 40 to 50% RH.

### Electronic Device

According to an exemplary embodiment of the present invention, an electronic device including: a substrate; an electronic element main body formed on the substrate; and a sealing substrate that is bonded to the substrate via a bonding part disposed on the surrounding of the electronic element main body to seal the electronic element main body; wherein at least one of the substrate and the sealing substrate is a gas barrier film, and the bonding part contains at least one kind selected from the group consisting of iron, cobalt, nickel, ruthenium, rhodium, palladium, osmium, iridium and platinum, is provided.

In order to provide an electronic device that is excellent in sealing property and resistance to repetitive bending, the present invention is characterized in the substrate and the sealing substrate, and the bonding part between the substrate and the sealing substrate. That is, at least one of the substrate and the sealing substrate is a gas barrier film, and the bonding part contains at least one kind selected from the group consisting of iron, cobalt, nickel, ruthenium, rhodium, palladium, osmium, iridium and platinum. By such constitution, the substrate and the sealing substrate are firmly bonded via the bonding part, and the entering of oxygen and water content into the main body of the electronic element can be prevented, and thus an electronic device that is excellent in sealing property and resistance to repetitive bending can be provided.

The exemplary embodiments of the present invention will be explained below with referring to the attached drawings. The present invention is not limited to only the following exemplary embodiments. Furthermore, there are some cases when the size ratio in the drawing is exaggerated for convenience of explanation and thus is different from the actual ratio.

The electronic device of the present invention may be, for example, an organic EL element. In the following explanation, as a typical exemplary embodiment, the case when the electronic device of the present invention is an organic EL element will be exemplified and explained, but the technical scope of the present invention is not limited to only the following embodiment.

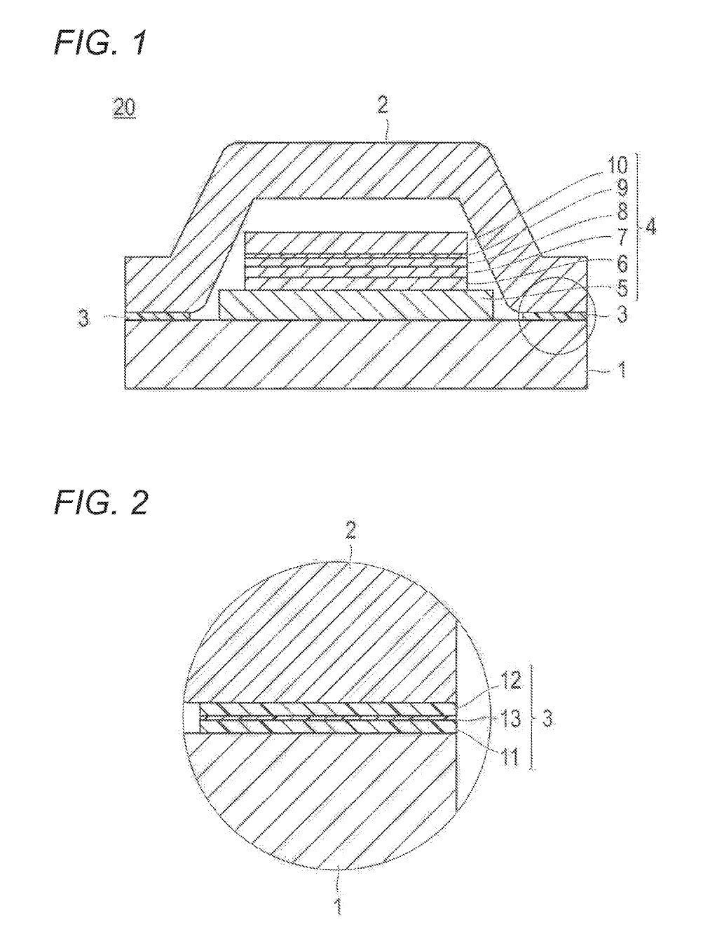

FIG. 1 is a cross-sectional schematic view of the electronic device 20 in an exemplary embodiment of the present invention. Specifically, the electronic device 20 shown in FIG. 1 has a substrate 1, a sealing substrate 2, a bonding part 3 that is positioned between the substrate 1 and the sealing substrate 2, and an electronic element main body 4 that is sealed by the bonding of the substrate 1 and the sealing substrate 2 through the bonding part 3. Furthermore, the electronic element main body 4 is a main body of an organic EL element main body, and can be formed by stacking a first electrode layer (anode) 5, a hole transport layer 6, a light-emitting layer 7, an electron transport layer 8, an electron injection layer 9 and a second electrode layer (cathode) 10 in this order.

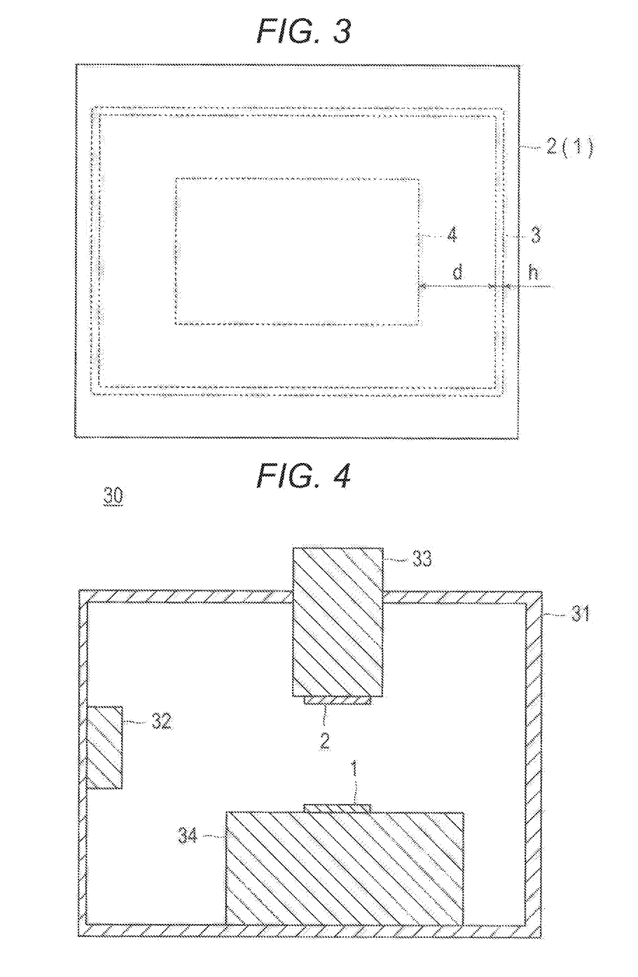

In the present invention, the electronic element main body 4 is disposed on the substrate 1, a first bonding margin is formed on the surrounding of the electronic element main body 4, a second bonding margin is formed on the part corresponding to the first bonding margin on the surface that is bonded to the substrate 1 of the sealing substrate 2, and the first and second bonding margins are bonded by bringing them into contact, whereby the bonding part 3 can be formed. As shown in FIG. 3, the bonding part 3 is present on the surrounding of the electronic element main body 4. As used herein, “surrounding” of the electronic element main body 4 means the surrounding that is apart from the peripheral edge of the electronic element main body 4 at a predetermined interval d as shown in FIG. 3.

FIG. 2 is a partial cross-sectional schematic view that shows the bonding part 3 in the present invention in close-up. As shown in FIG. 2, the bonding part 3 can be constituted by a silicon film (Si film) 11, a metal film 13 and a silicon film (Si film). More specifically, the bonding part 3 can have a layer structure in which the silicon film 11; the metal film 13 containing at least one kind selected from the group consisting of iron, cobalt, nickel, ruthenium, rhodium, palladium, osmium, iridium and platinum; and a silicon film 12 in this order.

Furthermore, the electronic device 20 may have other layers in addition to the substrate 1, the sealing substrate 2, the bonding part 3 and the electronic element main body 4 explained above. The other layers herein are not specifically limited, and examples include a stabilizing layer (not depicted) for stabilizing the electrode or the electronic element main body, a gas absorbing layer (not depicted), and the like.

The elements constituting the electronic device of the present invention will be explained below in detail.

### <Substrate>

The substrate in the present invention is not specifically limited, and examples include glass substrates, metal foils, gas barrier films and the like. In the present invention, from the viewpoint of ensuring of gas barrier property and flexibility, it is necessary that at least one of the substrate and the sealing substrate is a gas barrier film, and in order to impart higher gas barrier property and flexibility, it is more preferable that both of the substrate and the sealing substrate are gas barrier films. That is, it is preferable that the substrate is a first gas barrier film, and the sealing substrate is a second gas barrier film. The first gas barrier film and second gas barrier film herein do not have any special meaning, and are merely described for the convenience of distinguishing the case when the gas barrier film is used as a substrate and the gas barrier film is used as a sealing substrate, and the first gas barrier film and the second gas barrier film may have an identical constitution (material, layer constitution), or may have a different constitution.

Examples of the glass substrate include quartz glass substrates, borosilicate glass substrates, soda glass substrates, alkali-free glass substrates and the like. The metal foils include metal foils of aluminum (Al), gold (Au), silver (Ag), chromium (Cr), iron (Fe), nickel (Ni), cobalt (Co), copper (Cu), indium (In), tin (Sn), lead (Pb), titanium (Ti) and alloys thereof, and the like.

In the present invention, the substrate and the sealing substrate mentioned below each has a water vapor permeation degree at 60° C. and 90% RH (relative humidity) of preferably 5×10⁻³ g/m²·day or less, more preferably 5×10⁻⁴ g/m²·day or less, further preferably 5×10⁻⁵ g/m²·day or less.

Furthermore, in the present invention, it is preferable that the substrate and the sealing substrate mentioned below have flexibility. In addition, in the present specification, “flexibility” refers to a property such that the substrate has flexibility, and deflects and deforms when force is applied thereto and returns to the original shape when the force is removed, and specifically refers to that the bending elasticity as prescribed in JIS K7171: 2008 is, for example, from 1.0×10³ to 4.5×10³ [N/mm²] or less.

The first gas barrier film, which is preferably used as the substrate, will be explained below.

### First Gas Barrier Film

In the present invention, the first gas barrier film has a substrate and a gas barrier layer. The first gas barrier film may contain other element between the substrate and the gas barrier layer, on the gas barrier layer, or the other surface on which the gas barrier layer is not formed of the substrate. The other element is not specifically limited, and elements that are used in conventional gas barrier films can be used similarly or with suitable modification. Specific examples include functionalized layers such as an intermediate layer, a smooth layer and a bleed-out preventing layer.

Furthermore, in the present invention, it is sufficient that the gas barrier layer is formed on at least one surface of the substrate. Therefore, the first gas barrier film encompasses both of an embodiment in which a gas barrier layer is formed on one surface of the substrate, and an embodiment in which gas barrier layers are formed on the both surfaces of the substrate.

### (Substrate)

The substrate may be either a sheet-like or long substrate, and is preferably a long substrate. The substrate can retain a gas barrier layer having a gas barrier property (simply referred to as “barrier property”) mentioned below, and is formed by the materials as mentioned below, but the materials are not specifically limited to these.

Examples of the substrate can include films of respective resins such as polyacrylic acid esters, polymethacrylic acid esters, polyethylene telephthalate (PET), polybutylene telephthalate, polyethylene naphthalate (PEN), polycarbonates (PC), polyarylates, polyvinyl chloride (PVC), polyethylene (PE), polypropylene (PP), cycloolefin polymers (COP), cycloolefin copolymers (COC), cellulose triacetate (TAC), styrenes (PS), nylons (Ny), aromatic polyamides, polyether ether ketones, polysulfones, polyethersulfones, polyimides and polyetherimides, heat-resistant transparent films having silsesquioxane having an organic-inorganic hybrid structure as a basic backbone (product name: Sila-DEC; manufactured by Chisso Corporation, and Silplus (registered trademark); manufactured by Nippon Steel & Sumikin Chemical Co., Ltd.), and resin films constituted by stacking two or more of the above-mentioned resins, and the like.

In view of cost and availability, polyethylene telephthalate (PET), polybutylene telephthalate, polyethylene naphthalate (PEN), polycarbonates (PC) and the like are preferably used, and these are manufactured by a cast process due to their optical transparency and small birefringence. TAC, COC, COP, PC and the like are preferably used, and in view of optical transparency, heat-resistance, and tight-adhesiveness with the gas barrier layer, heat-resistant transparent films having a silsesquioxane having an organic-inorganic hybrid structure as a basic backbone are preferably used.

On the other hand, for example, in the case when a gas barrier film is used for use in an electronic device of a flexible display, there are some cases when the processing temperature goes beyond 200° C. in a step of preparing an array. In the case of manufacturing by roll-to-roll, since a certain tension is always applied to the substrate, when the substrate is put under a high temperature and the substrate temperature raises, if the substrate temperature goes beyond a glass transition point, it is concerned that the elastic modulus of the substrate rapidly decreases, and the substrate is stretched by the tension and damages the gas barrier layer. Therefore, in such use, it is preferable to use a heat-resistant material having a glass transition point of 150° C. or more as the substrate. In other words, it is preferable to use polyimides and polyetherimides, and heat-resistant transparent films having a silsesquioxane having an organic-inorganic hybrid structure as a basic backbone. However, since heat-resistant resins as represented by these are non-crystalline, these have a large water absorption rate as compared to those of crystalline PET and PEN, and thus it is concerned that the change in the size of the substrate by the humidity increases more, and the gas barrier layer is damaged. However, even in the cases when these heat-resistant materials are used as the substrate, the change in size due to the absorption and desorption of moisture of the substrate film itself under severe conditions of a high temperature and a high humidity can be suppressed by forming gas barrier layers on the both surfaces, and thus the damage on the gas barrier layer can be suppressed. Therefore, one of more preferable embodiments is such that the heat-resistant material is used as the substrate, and the gas barrier layers are formed on the both surfaces. Furthermore, in order to decrease the expansion and contraction of the substrate at the time of a high temperature, substrates containing glass fibers, cellulose and the like are also preferably used.

Furthermore, the substrate in the present invention may be a substrate that has undergone an easy-adhesion processing on one surface or both surfaces, or may be a substrate having clear hard coat layer(s) disposed on one surface or both surfaces.

The thickness of the substrate is preferably about from 5 to 500 μm, more preferably from 25 to 250 μm.

Furthermore, the substrate is preferably transparent. That the substrate is transparent as used herein represents that the light transmittance of visible ray (400 to 700 nm) is 80% or more.

This is because the substrate is transparent and the gas barrier layer formed on the substrate is also transparent, and thus it is possible to form a transparent gas barrier film, and it is also possible to form a transparent substrate of an organic EL element and the like.

Furthermore, the substrate using the resins and the like listed above may be either unstretched films or stretched films.

Furthermore, in the substrate in the present invention, the surface of the substrate may be subjected to a corona treatment before forming a gas barrier layer.

The surface roughness of the substrate used in the present invention is such that a ten-point average roughness Rz defined in JIS B0601: 2001 is preferably in the scope of from 1 to 500 nm, more preferably in the scope of from 5 to 400 nm, further preferably in the scope of from 300 to 350 nm.

Furthermore, the center line average surface roughness (Ra) defined by JIS B0601:2001 on the substrate surface is preferably in the range of from 0.5 to 12 nm, more preferably in the range of from 1 to 8 nm.

(Gas barrier layer)

The material for the gas barrier layer used in the present invention is not specifically limited, and various inorganic barrier materials can be used. Examples of the inorganic barrier materials include, for example, single bodies of at least one kind of metals selected from the group consisting of metal silicon (Si), aluminum (Al), indium (In), tin (Sn), zinc (Zn), titanium (Ti), copper (Cu), cerium (Ce) and tantalum (Ta), and metal compounds such as oxides, nitrides, carbides, acid nitrides or oxide carbides and the like of the above-mentioned metals.

More specific examples of the above-mentioned metal compounds include inorganic barrier materials such as metal oxides such as silicon oxide, aluminum oxide, titanium oxide, indium oxide, tin oxide, indium tin oxide (ITO), tantalum oxide, zirconium oxide, niobium oxide, aluminum silicate (SiAlOₓ), boron carbide, tungsten oxide, silicon oxide, oxygen-containing silicon oxide, aluminum nitride, silicon nitride, boron nitride, aluminum oxynitride, silicon oxynitride, boron oxynitride, zirconium oxyborate, titanium oxyborate, and composites thereof, inorganic barrier materials such as metal nitrides, metal carbides, metal oxynitrides, metal oxyborates, diamond-like carbon (DLC), and combinations thereof. Indium tin oxide (ITO), silicon oxide, aluminum oxide, aluminum silicate (SiAlOx), silicon nitride, silicon oxynitride and combinations thereof are specifically preferable inorganic barrier materials. ITO is an example of a specific element of a ceramic material that can be electroconductive by suitably selecting the respective elemental components.

Furthermore, the gas barrier layer in the present invention may also contain an organic layer containing an organic polymer. That is, the gas barrier layer may be a stacked body of the inorganic layer containing the above-mentioned inorganic barrier material and the organic layer.

The organic layer can be formed by, for example, applying an organic monomer or an organic oligomer onto the substrate to form a layer, and then conducting polymerization by using an electron beam device, a UV light source, a discharging device, or other preferable device, and conducting crosslinking as necessary. Furthermore, for example, the organic layer can also be formed by depositing an organic monomer or an organic oligomer that can be flash-vaporized and crosslinked by radiation, and forming a polymer from the organic monomer or the organic oligomer. The coating efficiency can be improved by cooling the substrate. Examples of the method for applying the organic monomer or organic oligomer include roll coating (for example, gravure roll coating), spray coating (for example, electrostatic spray coating) and the like. Furthermore, examples of the stacking body of the inorganic layer and the organic layer include the stacking bodies described in WO 2012/003198 A and WO 2011/01 3341 A.

In the present invention, the first gas barrier film may have a gas barrier layer of a single layer, or may have two or more of similar gas barrier layers or different gas barrier layers by stacking. Furthermore, in the case when two or more of the gas barrier layers in the present invention are stacked, the gas barrier layers may be gas barrier layers formed by a similar formation method, or may be gas barrier layers formed by different formation methods.

Furthermore, the surface center line average roughness (Ra) of the gas barrier layer in the present invention is not specifically limited, and is preferably 10 nm or less, more preferably 5 nm or less, further preferably 2 nm or less, and specifically preferably 0.5 nm or less, since it is preferable that the bonding surface is planarized as possible so as to seal the electronic element main body mentioned below.

The method for forming the gas barrier layer in the present invention will be explained below.

(Method for forming gas barrier layer)

In the present invention, the method for forming the gas barrier layer is not specifically limited, and a physical vapor deposition process (PVD process), a sputtering process, a chemical vapor deposition process (CVD process), or vapor film formation processes such as an atomic layer deposition process (ALD process), or a method of forming by a modification treatment of a coating formed by applying an application liquid containing an application liquid, preferably an application liquid containing a polysilazane compound (hereinafter simply referred to as “application process”) are preferably used. Furthermore, the application process is used more preferably from the viewpoint that the surface center line average roughness (Ra) of the gas barrier layer is easily controlled.

The vapor film formation process and application process will be explained below.

### Vapor Film Formation Process

The physical vapor deposition (PVD) process is a method for depositing a thin film of an intended substance such as a carbon film by a physical means on the surface of a substance in a vapor phase, and examples include sputtering processes (a DC sputtering process, a RF sputtering process, an ion beam sputtering process, and a magnetron sputtering process, and the like), a vacuum deposition process, an ion plating process, and the like.

The sputtering process is a method in which a target is installed in a vacuum chamber, allowing a rare gas (generally argon) that has been ionized by applying a high voltage to come into collision with a target such as silicon oxide (SiOₓ) to thereby plunk the atoms from the surface of the target and the atoms are attached to the substrate. At this time, a reactive sputtering process in which elements that have been plunked from the target by the argon gas and nitrogen or oxygen are reacted to form an inorganic layer by introducing a nitrogen gas or an oxygen gas into a chamber may also be used.

The chemical vapor deposition process (CVD process) is a method in which a raw material gas containing the components of an intended thin film is fed onto a substrate, and a film is deposited by a chemical reaction on the surface of the substrate or in a vapor phase. Furthermore, there are a method of generating plasma and the like for the purpose of activating a chemical reaction, and the like, and examples include known CVD systems such as a thermal CVD process, a catalyst chemical vapor deposition process, a light CVD process, a vacuum plasma CVD process and an atmospheric pressure plasma CVD process, and the like. Although the process is not specifically limited, in view of film formation velocity and treatment surface area, it is preferable to apply a plasma CVD process such as a vacuum plasma CVD process or an atmospheric pressure plasma CVD process, or the like.

The atomic layer deposition process (ALD process) is a method utilizing chemical adsorption or a chemical reaction of plural low energy gases on the surface of a substrate. The sputtering process and CVD process utilize high energy particles and thus causes pinholes and damages of the generated thin film, whereas this method is a method utilizing plural low energy gases, and thus has advantages that pinholes and damages occur little and thus a high-density monoatomic film can be obtained (JP 2003-347042 A, JP 2004-535514 T and WO 2004/105149 A).

### Application Process

In the present invention, the application process is a method that is conducted by applying an application liquid containing components for constituting a layer (for example, a gas barrier layer) by using a conventionally-known wet application method. Specific examples of such application process include a spin coat process, a roll coat process, a flow coat process, an inkjet process, a spray coat process, a print process, a dip coat process, a die coat process, a cast film formation process, a bar coat process, a gravure print process and the like.

It is preferable that the gas barrier layer in the present invention is formed by an application process. Specifically, it is preferable to form by a modification treatment of a coating that is formed by an application liquid containing a polysilazane compound.

<Polysilazane compound>

In the present invention, the polysilazane compound is a polymer having silicon-nitrogen bonds. Specifically, it is a ceramic precursor inorganic polymer of SiO₂ and Si₃N₄, which have bonds such as Si-N, Si-H and N-H, and an intermediate solid-solution of both, SiOₓN_{y}, and the like. In this specification, “polysilazane compound” is also abbreviated as “polysilazane”.

The polysilazane compound preferably has a structure of the following general formula (I).

### CHEMICAL FORMULA 1

### General formula (I)

—[Si (R₁) (R₂) —N (R₃)]—

In the above-mentioned general formula (I), R₁, R₂ and R₃ are each independently a hydrogen atom, or a substituted or unsubstituted alkyl group, aryl group, vinyl group or (trialkoxysilyl)alkyl group. At this time, R₁, R₂ and R₃ may be the same or different from one another. Examples of the alkyl group include straight chain, branched chain or cyclic alkyl groups having a carbon atom number of from 1 to 8. More specific examples include a methyl group, an ethyl group, an n-propyl group, an isopropyl group, an n-butyl group, an isobutyl group, a sec-butyl group, a tert-butyl group, an n-pentyl group, an isopentyl group, a neopentyl group, an n-hexyl group, an n-heptyl group, an n-octyl group, a 2-ethylhexyl group, a cyclopropyl group, a cyclopentyl group, a cyclohexyl group and the like. Furthermore, examples of the aryl group include aryl groups having a carbon atom number of from 6 to 30. More specific examples include non-condensed hydrocarbon groups such as a phenyl group, a biphenyl group, a terphenyl group and the like; and condensed polycyclic hydrocarbon groups such as a pentalenyl group, an indenyl group, a naphthyl group, an azulenyl group, a heptalenyl group, a biphenylenyl group, a fluorenyl group, an acenaphthylenenyl group, a preadenyl group, an acenaphthenyl group, a phenalenyl group, a phenanthryl group, an anthryl group, a fluoranetenyl group, an acephenanethrylenyl group, an aceantrilenyl group, a triphenylenyl group, a pyrenyl group, a crycenyl group, a naphthacenyl group and the like. Examples of the (trialkoxysilyl)alkyl group include alkyl groups having a carbon atom number of from 1 to 8 and having a silyl group substituted with an alkoxy group having a carbon atom number of from 1 to 8. More specific examples include a 3-(triethoxysilyl)propyl group, a 3-(trimethoxysilyl)propyl group and the like. The substituents that are optionally present in the above-mentioned R₁ to R₃ are not specifically limited, and examples include alkyl groups, halogen atoms, a hydroxy group (—OH), a mercapto group (—SH), a cyano group (—CN), a sulfo group (—SO₃H), a carboxy group (—COOH), a nitro group (—NO₂) and the like. The substituents that are optionally present are not the same as R₁ to R₃ that are substituted. For example, in the case when R₁ to R₃ are alkyl groups, R₁ to R₃ are not further substituted with an alkyl group. Among these, R₁, R₂ and R₃ are preferably a hydrogen atom, a methyl group, an ethyl group, a propyl group, an isopropyl group, a butyl group, an isobutyl group, a tert-butyl group, a phenyl group, a vinyl group, a 3-(triethoxysilyl)propyl group or a 3-(trimethoxysilylpropyl) group.

Furthermore, in the above-mentioned general formula (I), n is an integer that represents the number of the constitutional unit of the formula: —[Si(R₁) (R₂) —N(R₃)]—, and is preferably defined so that the polysilazane compound having a structure represented by the general formula (I) has a number average molecular weight of from 150 to 150,000 g/mol.

In the present invention, one of the preferable embodiments of the compound having a structure represented by the above-mentioned general formula (I) is perhydropolysilazane in which all of R₁, R₂ and R₃ are hydrogen atoms.

More specifically, for example, the gas barrier layer in the present invention can be formed by using or suitably modifying the gas barrier compound and application process described in paragraphs “0043” to “0063” and “0139” to “0173” of JP 2013-022799 A, or the gas barrier compound and application process described in paragraphs “0038” to “0123” of JP 2013-226758 A.

(Intermediate layer)

In the present invention, an intermediate layer may further be formed between the substrate of the gas barrier film (for example, the first gas barrier film, or the second gas barrier film mentioned below) and the gas barrier layer. It is preferable that the intermediate layer has a function to improve the adhesiveness between the substrate surface and the gas barrier layer. A commercially available substrate with an easy adhesive layer may also be preferably used.

(Smooth layer)

In the gas barrier film (for example, the first gas barrier film, or the second gas barrier film mentioned below) in the present invention, the above-mentioned intermediate layer may be a smooth layer. The smooth layer used in the present invention is provided so as to planarize a rough surface on which projections and the like are present of the substrate, or to planarize by filling unevenness and pinholes that have been generated on the gas barrier layer by the projections that are present on the substrate. Such smooth layer is basically prepared by curing a photosensitive material or a thermosetting material.

(Bleed-out layer)

In the gas barrier film in the present invention (for example, the first gas barrier film, or the second gas barrier film mentioned below), a bleed-out preventing layer may be disposed on the side of the surface of the substrate opposite to the surface on which the gas barrier layer is disposed. The bleed-out preventing layer can be provided. The bleed-out preventing layer is provided to the surface of the substrate opposite to the surface having the smooth layer, for the purpose of suppressing a phenomenon in which the unreacted oligomer and the like transfer to the surface from the film substrate when a film having a smooth layer is heated and contaminate the surface to be contacted. The bleed-out preventing layer may basically have the same constitution as that of the smooth layer as long as the bleed-out preventing layer has this function.

### Sealing Substrate

In the present invention, the sealing substrate is bonded to the above-mentioned substrate via a bonding part that is disposed on the surrounding of the main body of the electronic element to seal the main body of the electronic element. As shown in FIG. 1, the sealing substrate 2 is disposed so as to oppose the substrate 1 via the electronic element main body 4.

As the sealing substrate, the second gas barrier film, an element formed of only gas barrier layers that do not have substrates, or metal foils of aluminum (Al), gold (Au), silver (Ag), chromium (Cr), iron (Fe), nickel (Ni), cobalt (Co), copper (Cu), indium (In), tin (Sn), lead (Pb), titanium (Ti), and alloys thereof, and the like may also be used.

In order to impart higher gas barrier property and flexibility, it is more preferable that the sealing substrate is a second gas barrier film.

Since the substrate and gas barrier layer contained in the second gas barrier film are similar to the explanations in the substrate and gas barrier layer contained in the first gas barrier film, the explanations are omitted here.

In addition, in the case when the substrate is a first gas barrier film and the ealing substrate is a second gas barrier film, from the viewpoints of that the center line average roughness (Ra) of the joint surface can be controlled, the gas barrier property and sealing property are further improved, and the like, it is preferable that at least one of the first gas barrier film and the second gas barrier film contains a layer formed by modifying a coating formed by applying an application liquid containing a polysilazane compound, and it is more preferable that both of the first gas barrier film and the second gas barrier film contain layers that are formed by modifying coatings formed by applying an application liquid containing a polysilazane compound.

### Bonding

As shown in FIGS. 1 to 3, the bonding part 3 is disposed on the surrounding of the electronic element main body 4, and is present between the substrate 1 and the sealing substrate 3. The bonding part in the present invention contains at least one kind selected from the group consisting of iron, cobalt, nickel, ruthenium, rhodium, palladium, osmium, iridium and platinum. The substrate and the sealing substrate, at least one of which is a gas barrier film, are strongly bonded via such bonding part, whereby the entering of oxygen and water content into the electronic element main body can be prevented, and thus an electronic device that is excellent in sealing property and resistance to repetitive bending can be provided.

Furthermore, from the viewpoint of further improvement of the sealing property and the resistance to repetitive bending, it is preferable that bonding part in the present invention contains at least one kind selected from the group consisting of iron, cobalt and nickel.

Furthermore, in view of making the bonding property stronger, it is preferable that the bonding part in the present invention further contains silicon, germanium or tin, and the like, and it is more preferable that the bonding part contains silicon. In the case when such bonding part 3 further contains silicon, as shown in FIG. 2, an embodiment in which a silicon film 11, a metal film 13, a silicon film 12 and a sealing substrate 2 are stacked in this order on the stacking substrate 1 is more preferable. The method for forming the bonding part is not specifically limited, and a room-temperature bonding process mentioned below is preferably exemplified. Furthermore, the component(s) of the metal film 13 is/are preferably at least one kind of metal iron selected from the group consisting of cobalt, nickel, ruthenium, rhodium, palladium, osmium, iridium and platinum, more preferably at least one kind of metal iron selected from the group consisting of iron, cobalt and nickel.

The thickness of the bonding part in the present invention is not specifically limited, and is preferably from 3 to 100 nm, more preferably from 10 to 50 nm.

Furthermore, as shown in FIG. 3, the bonding part in the present invention 3 is present on a place at an interval d from the periphery of the electronic element main body 4. The values of the interval d may be identical or different on the respective sides of the periphery of the electronic element main body depending on the shape of the electronic device or the shape of the electronic element main body. Furthermore, the value of the interval d is preferably d≧10 μm, more preferably d≧100 μm depending on the size of the electronic device.

Furthermore, the width h of the bonding part 3 in the present invention is preferably from 10 to 2,000 μm, more preferably from 50 to 1,000 μm, depending on the size of the electronic device.

### Electronic Element Main Body

The electronic element main body is the main body of the electronic device. In the embodiment shown in FIG. 1, the electronic element main body 4 is an organic EL element main body. However, the electronic element main body in the present invention is not limited to such embodiment, and a main body of a known electronic device to which sealing with a gas barrier film can be applied can be used. Examples include solar batteries (PV), liquid crystal display elements (LCD), electronic papers, thin film transistors, touch panels and the like. The constitutions of the main bodies of these electronic devices are also not specifically limited, and the main bodies may have known constitutions.

In the embodiment shown in FIG. 1, the electronic element main body (organic EL element main body) 4 has a first electrode layer (anode) 5, a hole transport layer 6, a light-emitting layer 7, an electron transport layer 8, an electron injection layer 9 and a second electrode layer (cathode) 21, and the like. Furthermore, where necessary, a hole injection layer may be disposed between the first electrode layer 5 and the hole transport layer 6. In the organic EL element, the hole injection layer, the hole transport layer 6, the electron transport layer 8 and the electron injection layer 9 are optional layers that are disposed as necessary.

An organic EL element will be explained below as an example of the constitution of the specific electronic device.

[First electrode layer: anode]

As the first electrode layer (anode), those containing metals, alloys, electroconductive compounds each having a high work function (4 eV or more) and mixtures thereof as electrode substance(s) are preferably used.

[Hole injection layer: anode buffer layer]

A hole injection layer (anode buffer layer) may be allowed to present between the first electrode layer (anode) and the light-emitting layer or the hole transport layer. The hole injection layer is a layer that is disposed between an electrode and an organic layer for decreasing a driving voltage and improving a light emission luminance.

[Hole transport layer]

The hole transport layer is formed of a hole transport material having a function to transport holes, and the hole injection layer and the electron blocking layer can also be included in the hole transport layer in abroad sense. The hole transport layer can be disposed singly, or plural layers can be disposed.

[Light-emitting layer]

The light-emitting layer refers to a blue light-emitting layer, a green light-emitting layer and a red light-emitting layer. The order of stacking when the light-emitting layers are stacked is not specifically limited, and the respective light-emitting layers may have non-light-emitting intermediate layers therebetween.

[Electron transport layer]

The electron transport layer is formed of a material having a function to transport electrons, and is included in the electron transport layer in a broad sense. The electron injection layer is a layer that is disposed between an electrode and an organic layer for decreasing a driving voltage and improving a light emission luminance.

[Electron injection layer: cathode buffer layer]

The electron injection layer (cathode buffer layer), which is formed in the step of forming the electron injection layer, is formed of a material having a function to transport electrons, and is included in the electron transport layer in a significantly broad sense. The electron injection layer is a layer that is disposed between an electrode and an organic layer for decreasing a driving voltage and improving a light emission luminance.

[Second electrode layer: cathode]

As the second electrode layer (cathode), those containing metals, alloys, electroconductive compounds each having a low work function (4 eV or less) (these are referred to as electron injectable metals) and mixtures thereof as electrode substance(s) are preferably used.

[Protective layer]

Where necessary, the electronic device of the present invention may have a protective layer on the electronic element main body. The protective layer has a function to prevent substances that promote the deterioration of the electronic element main body such as water content and oxygen from entering into the element, a function to make the electronic element main body and the like disposed on the substrate insulative, or a function to solve bumps by the electronic element main body. The protective layer may be one layer, or plural layers may be stacked.

(Method for manufacturing electronic device)

Secondly, the method for manufacturing an electronic device will be explained.

According to an exemplary embodiment of the present invention, a method for manufacturing an electronic device, including the steps of: (1) preparing an electronic element main body formed on a substrate; (2) forming bonding margins each containing at least one kind selected from the group consisting of iron, cobalt, nickel, ruthenium, rhodium, palladium, osmium, iridium and platinum for bonding the substrate and the electronic element main body on the surface of the substrate and the surface of the sealing substrate, respectively; and (3) bringing the bonding margins into contact and forming a bonding part by room-temperature bonding, wherein at least one of the substrate and the sealing substrate is a gas barrier film, is provided.

The method for manufacturing an electronic device according to the above-mentioned exemplary embodiment of the present invention will be explained, but the present invention is not limited to this at all.
(1) The step of preparing an electronic element main body formed on a substrate

In this step, a substrate is firstly prepared by suitably referring to the explanation in the above-mentioned item of the substrate.

Subsequently, an electronic element main body is prepared on the substrate. Generally, the electronic element main body is prepared by stacking layers for constituting the electronic element main body such as a first electrode layer, a hole injection layer, a hole transport layer, a light-emitting layer, an electron transport layer, an electron injection layer, a second electrode layer and the like in this order on the substrate. The methods for forming these are not specifically limited, and these can be manufactured by suitably referring to known techniques.
(2) The step of forming bonding margins on the surface of the substrate and the surface of the sealing substrate, respectively

In this step, a sealing substrate is firstly prepared by suitably referring to the explanation in the above-mentioned item of sealing substrate.

Subsequently, the substrate having an electronic element main body prepared in the step (1) and the sealing substrate are installed in a known room-temperature bonding device so that they oppose and cover the electronic element main body, and the bonding margins thereof are respectively formed.

The room-temperature bonding device, which is used for respectively forming the bonding margins on the surface of the substrate and the surface of the sealing substrate, and for forming a bonding part by bonding at an ordinary temperature, which will be explained in the following step (3), will be explained below.

FIG. 4 is a cross-sectional schematic view showing an example of the room-temperature bonding device. The room-temperature bonding device 30 has a vacuum chamber 31, an ion gun (sputtering source) 32, a target stage 1 33 and a target stage 2 34.

The vacuum chamber 31 is a container for hermetically sealing the inside from environments, and further includes a vacuum pump (not depicted) for ejecting a gas from the inside of the vacuum chamber 31, and a lid (not depicted) for opening and closing a gate for connecting the inside and outside of the vacuum chamber 31. As the vacuum pump, a turbo molecular pump in which plural metal blades disposed therein flick gas molecules to thereby eject a gas is exemplified. The vacuum degree in the vacuum chamber 31 can be adjusted to be predetermined vacuum degree by a vacuum pump in the vacuum chamber 31.

The target stages 1 33 and 2 34 as metal release bodies are disposed so as to oppose. The respective opposing surfaces have dielectric layers. The target stage 1 33 applies a voltage to between the dielectric layer and the sealing substrate 2, and the sealing substrate 2 is adsorbed and fixed by the dielectric layer by an electrostatic force. Similarly, the target stage 2 34 adsorbs and fixes the substrate 1 via the dielectric layer.

The target stage 1 33 can be formed into a shape such as a columnar shape or a cubic shape, and can be transferred in equilibrium in the perpendicular direction with respect to the vacuum chamber 31. The parallel transfer is conducted by a pressure bonding mechanism (not depicted) disposed on the target stage 1 33. Furthermore, the target stage 1 33 may be formed from a metal that is intended to be sputtered on the substrate 1. For example, in the present invention, the target stage 1 33 can be formed from a metal containing at least one kind selected from the group consisting of iron, cobalt, nickel, ruthenium, rhodium, palladium, osmium, iridium and platinum.

The target stage 2 34 can be transferred in equilibrium in the perpendicular direction with respect to the vacuum chamber 31, or can be rotated around a rotational axis that is in parallel to the perpendicular direction. The parallel transfer and rotation are conducted by a perpendicular direction disposed on the target stage 2 34. Furthermore, the target stage 2 34 may be formed from a metal that is intended to be sputtered on the sealing substrate 2. For example, in the present invention, the target stage 2 34 can be formed from a metal containing at least one kind selected from the group consisting of iron, cobalt, nickel, ruthenium, rhodium, palladium, osmium, iridium and platinum.

An ion gun (also referred to as “sputtering source”) 32 is directed toward the substrate 1 and the sealing substrate 2. The ion gun 32 releases accelerated charged particles toward the direction to which the ion gun is directed. Examples of the charged particles include rare gas ions such as argon ion. Furthermore, in order to neutralize a subject that has been positively charged by the charged particles released by the ion gun 32, the vacuum chamber 31 may include an electron gun (not depicted).

By undergoing the irradiation of the charged particles, the metal is released by sputtering from the target stages 1 33 and 2 34 in the device, whereby sputtering is conducted on the desired parts of the substrate 1 and the sealing substrate 2, and metal films are formed as bonding margins on the desired parts. The ranges of the desired parts can be determined by a known technique of metal masking, and for example, by subjecting the parts of the electronic element main body to metal masking (not depicted) in sealing the electronic device of an exemplary embodiment of the present invention, a first bonding margin is formed on the surrounding part of the electronic element main body that has not been metal-masked on the substrate, and a second bonding margin is formed on the surrounding part has not been metal-masked on the sealing substrate.

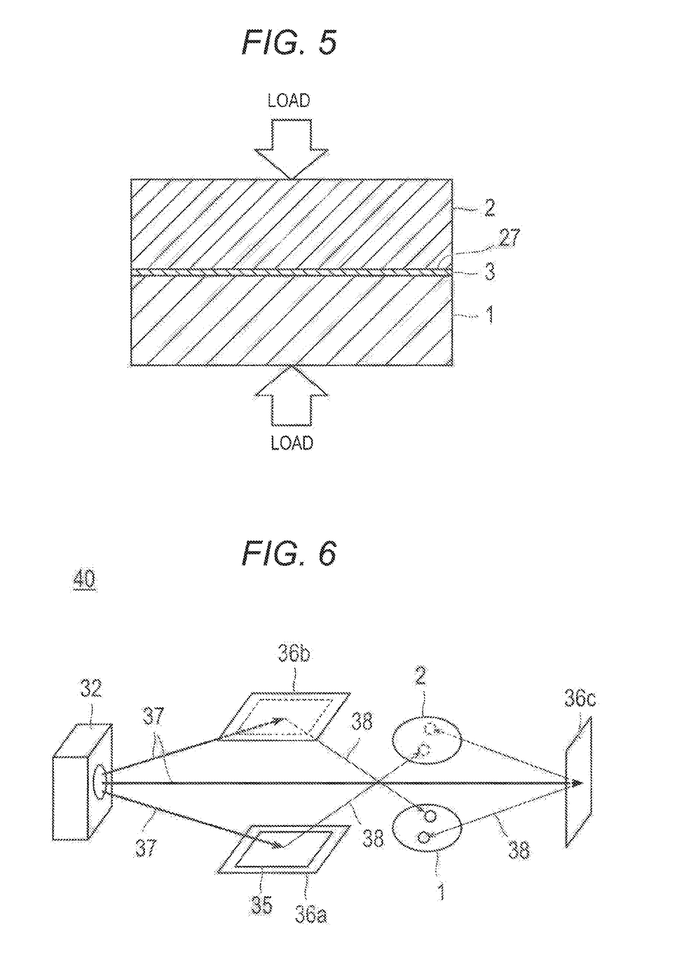

After the metal sputtering, the conditions for the irradiation of the charged particles are changed by adjusting the operation parameters of the ion gun 32 to thereby conduct the activation for bonding the respective bonding margins. Furthermore, the irradiation of the charged particles is completed, and the substrate 1 and the sealing substrate 2 are brought into contact as shown in FIG. 5 by allowing the target stage 1 33 to descent in the perpendicular direction by operating the pressure bonding mechanism of the target stage 1 33. By bonding in such way at an ordinary temperature, the substrate 1 and the sealing substrate 2 are bonded at the first and second bonding margins, and a bonding part 3 is formed at the interface 27 of the substrate 1 and the sealing substrate 2. By this way, the electronic element main body can be sealed.

In addition, one or two kind(s) of metal(s) can be sputtered on the substrate 1 and the sealing substrate 2 by the above-mentioned room-temperature bonding device, and when the room-temperature bonding device 40 shown in FIG. 6 is used, plural metals can be sputtered simultaneously or continuously. For example, in the case when the bonding part in the present invention further contains silicon, the room-temperature bonding device 40 shown in FIG. 6 is used more preferably. The room-temperature bonding device 40 will be simply explained below.

The room-temperature bonding device 40 has a sputtering source 32, target substrates 36a, 36b and 36c, and a pressure bonding mechanism (not depicted) for supporting the substrate 1 and the sealing substrate 2 in a vacuum chamber (not depicted).

A metal target 35 that is intended to be sputtered is installed in advance in the target substrates 36a, 36b and 36c. For example, in an exemplary embodiment of the present invention, a metal containing at least one kind selected from the group consisting of iron, cobalt, nickel, ruthenium, rhodium, palladium, osmium, iridium and platinum can be installed as the metal target for the target substrates 36a and 36b, and furthermore, a silicon target can be installed as the metal target for the target substrate 36c.

The parts on which the respective bonding margins are to be formed are determined in advance by metal masking on the substrate 1 and sealing substrate 2 to be bonded, and the substrate 1 and sealing substrate 2 are fixed on a substrate holder (not depicted) of the pressure bonding mechanism in the vacuum chamber. The fixing is not specifically limited, and the fixing can be conducted via an electrostatic layer in a similar manner to the case of the above-mentioned room-temperature bonding device 30. Furthermore, since the vacuum chamber herein is similar to the vacuum chamber 31 of the above-mentioned room-temperature bonding device 30, the explanation thereof is omitted.

After the vacuum degree inside of the vacuum chamber can be adjusted to be a predetermined vacuum degree, the sputtering source 32 is started, and a rare gas ion beam (this is similar to “charged particles” as referred to in the above-mentioned room-temperature bonding device 30) of argon ion or the like can be entered (irradiated) into the target substrates 36a, 36b and 36c, the substrate 1 or the sealing substrate 2 like as in the incident ray 37. As a specific example, when an argon ion beam has entered into (irradiated) the silicon target that is installed in the target substrate 36c, the silicon elements are launched, and the silicon elements reach and deposit on the bonding margin-forming parts of the substrate 1 and the sealing substrate 2 along the outgoing ray 38, whereby a silicon film can be formed. In addition, prior to the formation of the silicon film, it is preferable to conduct reverse sputtering as the cleaning of the surfaces of the bonding margin-forming parts by irradiating suitable argon ion beam, so as to remove the impurities, adsorbed gases, oxide films and the like adhered to the respective bonding margin-forming parts of the substrate 1 and the sealing substrate 2. The reverse sputtering refers to that a certain subject is irradiated with a certain energy ray to cause sputtering, whereby the irradiated part is physically scraped.

Secondly, when a metal to be installed on the target substrates 36a and 36b enters into (is irradiated to) the formed silicon film from argon ion beam, the metal elements are ejected, and the metal elements reach and deposite on the bonding margin-forming parts of the substrate 1 and the sealing substrate 2 along the outgoing ray 38, whereby a metal film can be formed on the silicon film.

Thereafter, reverse sputtering is conducted as the activation of the metal films (bonding margins) formed on the substrate 1 and the sealing substrate 2. At this time, the activation may be conducted simultaneously with the deposition for forming the metal films, by using an argon ion beam that has not entered into the metal target, or may be conducted after the formation of the metal films, and it is more preferable to conduct the activation by using an argon ion beam after the formation of the metal films in view of the convenience of the operations. In addition, since the degrees of the effects of the above-mentioned deposition and activation depend on the disposition of the metal target, the intensity of the energy ray from the sputtering source 32, and the energy density distribution in the direction vertical to the incident ray 37, the degrees can be adjusted by presetting those. As a matter of course, adjustment by which an action of the reverse sputtering which goes beyond the deposition is caused is not adopted.

Furthermore, the metal mask is removed, and the pressure bonding mechanism is operated in a similar manner to that in the above-mentioned explanation of the room-temperature bonding device 30, whereby the bonding part 3 is formed. By this way, the electronic element main body can be sealed.

In the present invention, if unevenness is present on the bonding margin-forming parts, then the formed bonding margins are also affected, and the smoothness of the surfaces of the bonding margins decreases, and thus sufficient contact cannot be conducted and thus the bonding may become insufficient. Therefore, the surface having the electronic element main body and the surface of the sealing substrate of the above-mentioned substrate used can be planarized by conducting mirror surface polishing. Alternatively, for example, in the case when both of the substrate and sealing substrate are gas barrier films, it is also possible to conduct planarization by decreasing the viscosity of the application (i.e., decreasing the solid content concentration in the application liquid) in forming the gas barrier layer by the above-mentioned application process. Meanwhile, the surface center line average roughnesses (Ra) of the above-mentioned substrate surface and the above-mentioned sealing substrate before forming the respective bonding margins are each preferably 10 nm or less, more preferably 5 nm or less, further preferably 2 nm or less, specifically preferably 0.5 nm or less.

It is preferable to clean the respective bonding margin-forming parts before forming the bonding margins, from the viewpoint of removal of the impurities, adsorbed gases, oxide films and the like adhered to the surfaces. The cleaning and post-operations are preferably conducted in vacuum so that the sealed electronic device would not contain water content, oxygen and the like therein. It is preferable to conduct the cleaning under an environment in which the vacuum degree is from 1 to 1×10⁻³ Pa. Furthermore, the cleaning can be conducted by a known technique such as reverse sputtering.

The reverse sputtering as an example for conducting the cleaning can be conducted as follows. It can be conducted by using an inert gas such as argon, and irradiating with presetting the acceleration voltage to from 0.05 to 5 kV, preferably from 0.08 to 3 kV, the electrical current value to from 0.5 to 100 mA, preferably to 0.8 to 80 mA, for from 0.1 to 60 minutes, preferably from 0.5 to 30 minutes.

Thereafter, it is preferable that the above-mentioned first and second bonding margins are formed by sputtering. The sputtering herein includes sputtering by irradiation of ion beam, sputtering by irradiation of neutral particles, sputtering by irradiation of plasma, sputtering by irradiation of laser beam, and the like.

In the present invention, the metal target for the sputtering is not specifically limited, and from the viewpoint of improvement of the sealing property repetative bending property, the metal target contains at least one kind selected from the group consisting of iron, cobalt, nickel, ruthenium, rhodium, palladium, osmium, iridium and platinum, preferably contains at least one kind selected from the group consisting of iron, cobalt and nickel.

Furthermore, in view of making the bonding property stronger, it is preferable to form a silicon film, a germanium film or a tin film or the like, more preferable to forma silicon film, on the respective bonding margin-forming parts of the substrate and the sealing substrate, before sputtering the metal target. The silicon film may be formed by sputtering a silicon target.

Meanwhile, the sputtering of the metal target or the silicon target (the silicon target used in the case when silicon is further contained) can be conducted by a known technique under an environment in which the vacuum degree is from 1 to 1×10⁻³ Pa.

Furthermore, the thicknesses of the silicon films formed on the first and second bonding margin-forming parts are not specifically limited as long as the effect of the present invention is not deteriorated, and are each preferably from 1 to 50 nm, more preferably from 5 to 30 nm. The thicknesses of the metal films are also not specifically limited as long as the effect of the present invention is not deteriorated, and are each preferably from 0.1 to 10 nm, more preferably from 1 to 5 nm.

By this way, the bonding margins for bonding the substrate and the sealing substrate for sealing the electronic element main body can be formed on the substrate surface and the sealing substrate surface, respectively.
(3) The step of bringing the bonding margins into contact and forming a bonding part by room-temperature bonding

In this step, the bonding margins formed in the step (2) are brought into contact, and bonded at an ordinary temperature, whereby a bonding part is formed.

Before the contacting, it is preferable to activate the surfaces of the metal films on the respective bonding margins. The activation can be conducted under a high vacuum environment in which the vacuum degree is from 1×10⁻⁵ to 1×10⁻⁹ Pa by a known technique such as reverse sputtering. For example, the activation is conducted by an ion beam of an inert gas such as argon, and can be conducted by irradiating with presetting the acceleration voltage to from 0.05 to 5 kV, preferably from 0.08 to 3 kV, the electrical current value to from 0.5 to 100 mA, preferably from 0.8 to 80 mA, for from 0.1 to 200 minutes, preferably from 0.5 to 100 minutes.

Secondly, the two metal masks are removed, and the activated first and second bonding margins can be bonded in vacuum at an ordinary temperature without pressurization, and it is preferable to apply a pressure of 0.2 to 10 MPa within 1 to 60 minutes in view of conducting bonding more firmly.

In the present invention, it is preferable that the bonding part formed as above is constituted by the silicon film; the metal film containing at least one kind selected from the group consisting of iron, cobalt, nickel, ruthenium, rhodium, palladium, osmium, iridium and platinum; and the silicon film in this order.

Based on the steps (1) to (3) explained above, an electronic device in which an electronic element main body is sealed can be manufactured. Specifically, in the step (3), the surface layers of the metal films of the respective bonding margins are activated, and the atoms exposed on the surfaces are in the state that a part of the bonds that form chemical bonds have lost bonding pairs, and thus are expected to have a strong bonding force against the atoms on the metal film on the another bonding margin, and when the bonding margins are bonded, metal bonds are formed. The bonding part formed by such way does not have a bonding interface, and is a metal having metal bonds itself, and has a high sealing property (tight adhesiveness) and a high flexilibity. That is, an electronic device that is excellent in sealing property, and also excellent in resistance to repetitive bending can be achieved.

### EXAMPLES

The effect of the present invention will be explained by using the following Examples and Comparative Examples. However, the technical scope of the present invention is not limited to only the following Examples. Furthermore, in the Examples, an indication of “parts” or “%” is used, and the indication represents “parts by mass” or “% by mass” unless otherwise specified.

Furthermore, in the following operations, the operation and measurements of the physical properties and the like were conducted under conditions of an ambient temperature (20 to 25° C.)/relative humidity 40 to 50% RH unless otherwise specified.

[Preparation of gas barrier film 1]

A PEN substrate (125 μm thickness) provided with a clear hard coat (125 μm thickness) manufactured by Kimoto Co., Ltd. was set in a vacuum bath of a sputtering device manufactured by ULVAC, Inc., the vacuum bath was evacuated to the order of 10⁻⁴ Pa, and argon as a discharging gas was introduced at a partial pressure of 0.5 Pa. At the time when the atmospheric pressure had been stabilized, discharging was initiated to allow generation of plasma on a silicon oxide (SiOₓ) target, and a sputtering process was initiated. The shutter was opened at the time when the process had been stabilized, and formation of a silicon oxide film (SiOₓ) on the film was initiated. The film formation was completed by closing the shutter at the time when a film of 300 nm had been deposited, whereby a gas barrier layer 1 was formed, and the gas barrier film 1 was prepared.

The surface center line average roughness (Ra) was measured for the obtained gas barrier film 1, and found to be 10 nm.

The surface center line average roughness (Ra) was obtained by measuring a center line roughness Ra when measured at a standard exceeding of 2.5 mm and a cutoff value of 0.8 mm as prescribed in JIS B0601: 2001 by using a non-contact three-dimensional microsurface shape measurement system (WYKO manufactured by Veeco). The following measurements were similarly conducted.

[Preparation of gas barrier film 2]

A dibutyl ether solution containing 20% by weight of catalyst-free perhydropolysilazane (NN120-20 manufactured by AZ Electronic Materials) and a dibutyl ether solution containing 20% by weight of perhydropolysilazane containing 5% by weight of an amine catalyst (N,N,N′,N′-tetramethyl-1,6-diaminohexane (TMDAH)) (Aquamica (registered trademark) NAX120-20 manufactured by AZ Electronic Materials) were mixed at a ratio of 4:1 (weight ratio), and an application liquid is prepared by diluting with a solvent in which dibutyl ether and 2,2,4-trimethylpentane had been mixed so that the mass ratio became 65:35, so that the solid content of the polysilazane in the application liquid became 15% by mass.

The application liquid obtained above was formed into a film on a PEN substrate provided with a clear hard coat (125 μm thickness) manufactured by Kimoto by using a spin coater so as to give a thickness of 300 nm, left for 2 minutes, and subjected to a thermal treatment on a hot plate at 80° C. for 1 minute, whereby a polysilazane coating was formed.

After the polysilazane coating was formed, polysilazane coating was subjected to a vacuum UV irradiation treatment at 6,000 mJ/cm² by using an Xe excimer lamp (Xe₂ type, 172 nm) under a nitrogen atmosphere (oxygencon centration: 5 volume ppm), whereby a gas barrier layer 2 was formed, and the gas barrier film 2 was prepared.

The surface centerline average roughness (Ra) was measured for the obtained gas barrier film 2, and found to be 2.0 nm.

[Preparation of gas barrier film 3]

A gas barrier film 3 was prepared in a similar manner to that in the preparation of the above-mentioned gas barrier film 2, except that the application liquid was prepared by diliting so that the solid content concentration of the polysilazane in the application liquid became 5% by mass.

The surface centerline average roughness (Ra) was measured for the obtained gas barrier film 3, and found to be 0.5 nm.

{Preparation of electronic device}

An organic EL element, which is an electronic device, was prepared by the following procedures.

### Example 1

[Preparation of organic EL element 1]
(Formation of first electrode layer)

A 90 mm square was cut out of the gas barrier film 1 prepared above, and prepared as a substrate. ITO (indium tin oxide) having a thickness of 150 nm was formed by a sputtering process on the gas barrier layer of the substrate, and patterning was conducted by a photolithography process, whereby a first electrode layer was formed.

In addition, the pattern was such a pattern that the light-emitting surface area became 50 mm square, and a metal rod was embedded from the opposite side of the gas barrier layer of the gas barrier film so as to contact with the first electrode layer to form an electrode extraction part, whereby the gas barrier layer part was left on the outer periphery of the light-emitting surface area.
(Formation of hole transport layer)

The application liquid for forming a hole transport layer shown below was applied by an applicator onto the first electrode layer formed above under an environment at 25° C. and a relative humidity of 50% RH, and drying and heating treatments were conducted under the following conditions to form a hole transport layer. The application liquid for forming a hole transport layer was applied so that the thickness of the hole transport layer after the drying became 50 nm.

Furthermore, before applying the application liquid for forming a hole transport layer, a washing surface modification treatment of the gas barrier film on which the first electrode layer had been formed was conducted by using a low pressure mercury lamp having a wavelength of 184.9 nm, at an irradiation intensity of 15 mW/cm² and a distance of 10 mm. The charge removal treatment was conducted by using a static eliminator by faint X-ray.

### Application Liquid for Forming Hole Transport Layer>

A solution obtained by diluting polyethylenedioxythiophene-polystyrene sulfonate (PEDOT/PSS, Bytron (registered trademark) P AI 4083 manufactured by Bayer) with pure water to 65% by mass, and diluting with methanol to 5% by mass was prepared as an application liquid for forming a hole transport layer.

### Conditions for Drying and Heating Treatments

The application liquid for forming a hole transport layer was applied, and the solvents were removed by blowing the film-formed surface with hot air at a height of 100 mm, an ejection wind velocity of 1 m/s, a transversal wind velocity distribution of 5% and a temperature of 100° C. Subsequently, a thermal treatment of a rear-surface heat transfer system was conducted by using a thermal treatment device at a temperature of 150° C., whereby a hole transport layer was formed.

(Formation of light-emitting layer)

An application liquid for forming a white light-emitting layer shown below was applied by an applicator onto the hole transport layer formed above under the following conditions, and drying and thermal treatments were conducted under the following conditions, whereby a light-emitting layer was formed. The application liquid for forming a white light-emitting layer was applied so that the thickness after the drying became 40 nm.

### Application Liquid for Forming White Light-Emitting Layer

An application liquid for forming a white light-emitting layer was prepared by dissolving 1.0 g of the compound represented by the following chemical formula H-A as a host material, 100 mg of the compound represented by the following chemical formula D-A as a dopant material, 0.2 mg of the compound represented by the following chemical formula D-B as a dopant material and 0.2 mg of the compound represented by the following chemical formula D-C as a dopant material in 100 g of toluene.

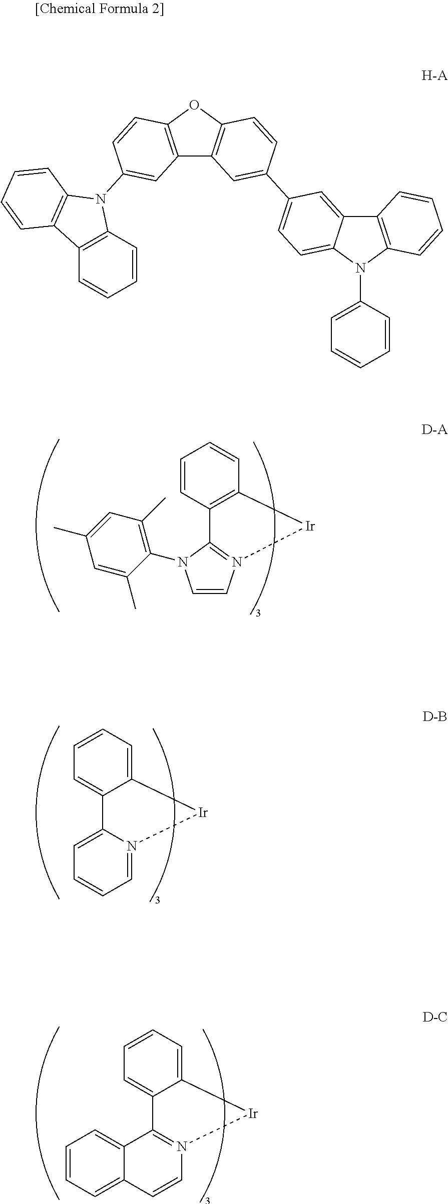

### Conditions for application

The application step was conducted under an atmosphere of a nitrogen gas concentration of 99% or more, at an application temperature of 25° C., and at an application velocity of 1 m/min.

### Conditions for drying and thermal treatments

The application liquid for forming a white light-emitting layer was applied, and the solvents were removed at a height of 100 mm, an ejection wind velocity of 1 m/s, a transversal wind velocity distribution of 5% and a temperature of 60° C. toward the film-formed surface. Subsequently, a thermal treatment was conducted at a temperature of 130° C., whereby a light-emitting layer was formed.

(Formation of electron transport layer)

The application liquid for forming an electron transport layer shown below was applied by an applicator onto the light-emitting layer formed above under the following conditions, and subjected to drying and thermal treatments under the following conditions, whereby an electron transport layer was formed. The application liquid for forming an electron transport layer was applied so that the thickness after the drying became 30 nm.

### Conditions for application

The application step was conducted under an atmosphere of a nitrogen gas concentration of 99% or more, at an application temperature of the application liquid for forming an electron transport layer of 25° C., and at an application velocity of 1 m/min.

### Application Liquid for Forming Electron Transport Layer

For the electron transport layer, an application liquid for forming an electron transport layer was prepared by dissolving the compound represented by the following chemical formula E-A in 2,2,3,3-tetrafluoro-1-propanol to give a 0.5% by mass solution.

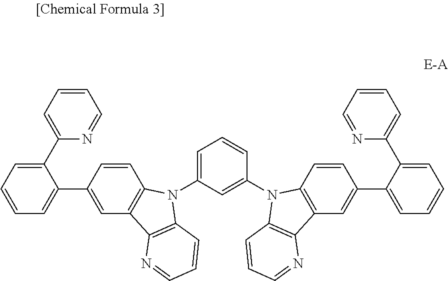 [SMILES: c1ccc(-c2ccccc2-c2ccc3c(c2)c2ncccc2n3-c2cccc(-n3c4ccc(-c5ccccc5-c5ccccn5)cc4c4ncccc43)c2)nc1]

### Conditions for Drying and Thermal Treatments

The application liquid for forming an electron transport layer was applied, and the solvent was removed by blowing the film-formed surface with hot air at a height of 100 mm, an ejection wind velocity of 1 m/s, a transversal wind velocity distribution of 5% and a temperature of 60° C. Subsequently, a thermal treatment was conducted on a thermal treatment part at a temperature of 200° C., whereby an electron transport layer was formed.

(Formation of electron injection layer)

An electron injection layer was formed on the electron transport layer formed above. Firstly, the substrate was put into a pressure reduction chamber, and the pressure was reduced to 5×10⁻⁴ Pa. Cesium fluoride, which had been prepared in a deposition boat made of tantalum in a vacuum chamber in advance, was heated, whereby an electron injection layer having a thickness of 3 nm was formed.

(Formation of second electrode layer)

A second electrode layer having a thickness of 100 nm was stacked on the part that was on the electron injection layer formed above, except the part that was to be an extraction electrode of the first electrode layer, by conducting mask pattern film formation so as to give a light emitting surface area of 50 mm square, under a vacuum of 5×10⁻⁴ Pa using aluminum as a material for forming a second electrode layer, so as to have an extraction electrode, by a deposition process, and a metal rod was embedded from the opposite side of the barrier layer of the gas barrier film so as to contact with the second electrode layer to form an electrode extraction part.

By this way, the electronic element main body 1 having the first electrode layer, the hole transport layer, the light-emitting layer, the electron transport layer, the electron injection layer and the second electrode layer was prepared.

### [Sealing]

A 90 mm square was newly cut out of the gas barrier film 1 prepared above, and prepared as a sealing substrate. The sealing substrate, and the gas barrier film having the electronic element main body 1 prepared above were installed in the room-temperature bonding device shown in FIG. 6 so that the respective gas barrier layers were opposed. A metal mask was formed on the electronic element main body 1 prepared above, and a metal mask having the same size as this metal mask was also formed on the corresponding part on the sealing substrate, reverse sputtering was then conducted under an environment of a vacuum degree of 1×10⁻¹ Pa by using an argon gas, and the respective surfaces of the substrate and sealing substrate were cleaned. The reverse sputtering was conducted by irradiating for 1 to 10 minutes at an acceleration voltage of from 0.1 to 2 kV and an electrical current value of from 1 to 20 mA.

Subsequently, a Si target was installed in the device under an environment of a vacuum degree of 1×10⁻¹ Pa, and Si films each having a thickness of 10 nm and a width of 350 μm were respectively formed by sputtering on the periphery part of the electronic element main body 1 and the corresponding part on the sealing substrate. Subsequently, a Ru target was installed, and Ru films each having a thickness of 1 nm and a width of 350 μm were respectively formed on the Si films to form bonding margins.

Subsequently, reverse sputtering was conducted again on the Ru films by using an argon gas under an environment of a vacuum degree of 1×10⁻⁷ Pa to thereby activate the surfaces of the respective Ru films (bonding margins). The reverse sputtering was conducted by irradiating for 1 to 10 minutes at an acceleration voltage of from 0.1 to 2 kV and an electrical current value of from 1 to 20 mA. The metal masks were then removed, and the bonding margins were bonded to each other by pressurizing at 1 MPa for 10 minutes, whereby the electronic element main body 1 was sealed.

(Connection of electrode lead)

A flexible printing substrate (base film: polyimide 12.5 μm, rolled copper foil 18 μm, cover lay: polyimide 12.5 μm, surface treatment NiAu plating) was connected to the sealed electronic element main body 1 by using an anisotropic electroconductive film DP3232S9 manufactured by Sony Chemical & Information Device Corporation, whereby an organic EL element 1 was prepared.

Pressure bonding was conducted under the pressure bonding condition of a temperature of 170° C. (an ACF temperature measured by separately using a thermocouple of 140° C.), a pressure of 2 MPa and 10 seconds.

### Example 2

[Preparation of organic EL element 2]

An organic EL element 2 was prepared in a similar manner to that in the preparation of the above-mentioned organic EL element 1, except that a Co target was used instead of the Ru target in the formation of the bonding margins.

### Example 3

[Preparation of organic EL element 3]

An organic EL element 3 was prepared in a similar manner to that in the preparation of the above-mentioned organic EL element 1, except that a Fe target was used instead of the Ru target in the formation of the bonding margins.

### Example 4

[Preparation of organic EL element 4]

An organic EL element 4 was prepared in a similar manner to that in the preparation of the above-mentioned organic EL element 1, except that a Fe-Co mixed target (Fe-Co; Fe: Co=75:25 [molar ratio]) was used instead of the Ru target in the formation of the bonding margins.

### Example 5

[Preparation of organic EL element 5]

An organic EL element 5 was prepared in a similar manner to that in the preparation of the above-mentioned organic EL element 3, except that the gas barrier film 2 was used instead of the gas barrier film 1 as the substrate and the sealing substrate.

### Example 6

[Preparation of organic EL element 6]

An organic EL element 6 was prepared in a similar manner to that in the preparation of the above-mentioned organic EL element 3, except that the gas barrier film 3 was used instead of the gas barrier film 1 as the substrate and the sealing substrate.

### Comparative Example 1

[Preparation of organic EL element 7]

An organic EL element 7 was prepared in a similar manner to that in the preparation of the above-mentioned organic EL element 1, except that only Si films were formed in forming the bonding margins, and that the bonding margins formed of the Si films were bonded.

### Comparative Example 2

[Preparation of organic EL element 8]

An organic EL element 8 was prepared in a similar manner to that in the preparation of the above-mentioned organic EL element 1, except that the sealing of the electronic element main body 1 was conducted by using a Sn42/Bi58 alloy sealant having a melting point of 139° C.

The Sn42/Bi58 alloy sealant was prepared according to a conventional method, and the organic EL element 8 was prepared by melting the alloy sealant as it is, attaching the alloy sealant to the periphery of the electronic element main body 1 immediately after ejection by using a dispenser and cooling the alloy sealant by allowing to stand at an ambient temperature to thereby seal the electronic element main body 1.

{Evaluation of organic EL element}

For the organic EL elements 1 to 8 prepared above, the sealing property and resistance to repetitive bending were evaluated according to the following methods.

[Evaluation of sealing property]

The sealing property of each organic EL element was evaluated by subjecting the organic EL element to an accelerated deterioration treatment, and evaluating dark spots.

(Accelerated deterioration treatment)

Each of the organic EL elements 1 to 8 prepared above was subjected to an accelerated deterioration treatment for 1,000 hours under an environment at 85° C. and 85% RH, and the following evaluation relating to the dark spots was conducted.

(Evaluation of dark spots (DS, black points))

An electrical current of 1 mA/cm² was applied on the organic EL element that has undergone the accelerated deterioration treatment, and the organic EL element was allowed to continuously emit light for 24 hours. A part of the panel was enlarged by a 100-fold microscope (MS-804 manufactured by MORITEX Corporation, lens MP-ZE25-200), and photographed. The photographed image was cut into a shape corresponding to a 2 mm square scale, the ratio of the surface area on which dark spots had generated was obtained, and the sealing property was evaluated according to the following criteria.

When the evaluation rank was Δ, the property was judged to be practical, when the rank was ◯, the property was judged to be more practical, and when the rank was ⊙, the property was judged to be a preferable property without any problem.
⊙: The dark spot generation rate is lower than 0.3%,
◯: the dark spot generation rate is 0.3% or more and lower than 1.0%,
Δ: the dark spot generation rate is 1.0% or more and lower than 2.0%,
×: the dark spot generation rate is 2.0% or more and lower than 5.0%,
××: the dark spot generation rate is 5.0% or more.

The results of the evaluation are shown in the following Table 1.

[Evaluation of resistance to repetitive bending]

The organic EL elements 1 to 8 prepared above were each repeatedly bent 500 times at angle of 180° by a method based on JIS C5016-1994, so that the curvature became a radius of 5 mm, the traverse distance became 40 mm, and the traverse velocity became 20 mm/sec.

Each organic EL element after the repetitive bending was subjected to an acceleration deterioration treatment under an environment of 85° C. and 85% RH for 100 hours, and the resistance to repetitive bending was evaluated in a similar manner to that of the evaluation of the above-mentioned dark spots.

When the evaluation rank was Δ, the property was judged to be practical, when the rank was ◯, the property was judged to be more practical, and when the rank was ⊙, the property was judged to be a preferable property without any problem.
⊙: The dark spot generation rate is lower than 0.3%,
◯: the dark spot generation rate is 0.3% or more and lower than 1.0%,
Δ: the dark spot generation rate is 1.0% or more and lower than 2.0%,
×: the dark spot generation rate is 2.0% or more and lower than 5.0%,
××: the dark spot generation rate is 5.0% or more.

The results of the evaluation are shown in the following Table 1.

TABLE 1

| | | Gas barrier | | | | |
|---|---|---|---|---|---|---|
| | | film | | | | Evaluation |
| | | | Surface | | | of |
| | | | centerline | | | resistance |
| | Organic EL | | average | | Evaluation | to |
| | element | | roughness | Layer constitution | of sealing | repetitive |
| | No. | No. | Ra (nm) | of bonding part | property | bending |
| Example 1 | 1 | 1 | 10 | Si film/Ru film/Si | Δ | Δ |
| | | | | film | | |
| Example 2 | 2 | 1 | 10 | Si film/Co film/Si | ◯ | Δ |
| | | | | film | | |
| Example 3 | 3 | 1 | 10 | Si film/Fe film/Si | ◯ | Δ |
| | | | | film | | |
| Example 4 | 4 | 1 | 10 | Si film/Fe—Co | ◯ | Δ |
| | | | | film/Si film | | |
| Example 5 | 5 | 2 | 2.0 | Si film/Fe film/Si | ◯ | ◯ |
| | | | | film | | |
| Example 6 | 6 | 3 | 0.5 | Si film/Fe film/Si | ⊙ | ⊙ |
| | | | | film | | |
| Comparative | 7 | 1 | 10 | Si film | X | X |
| Example 1 | | | | | | |
| Comparative | 8 | 1 | 10 | Sn42/Bi58 | X | XX |
| Example 2 | | | | | | |

As is apparent from the results described in the above-mentioned Table 1, it is understood that the electronic devices 1 to 6 of the present invention are excellent in sealing property (tight-adhesiveness) and also excellent in resistance to repetitive bending.

The present application is based on the Japanese Patent Application No. 2013-156145 filed on Jul. 26, 2013, and the entirety of the contents of the disclosure is herein incorporated by reference.

1. An electronic device comprising:
a substrate;
an electronic element main body formed on the substrate; and
a sealing substrate that is bonded to the substrate via a bonding part disposed on the surrounding of the electronic element main body to seal the electronic element main body;
wherein at least one of the substrate and the sealing substrate is a gas barrier film, and
the bonding part contains at least one kind selected from the group consisting of iron, cobalt, nickel, ruthenium, rhodium, palladium, osmium, iridium and platinum.

2. The electronic device according to claim 1, wherein the bonding part contains at least one kind selected from the group consisting of iron, cobalt and nickel.

3. The electronic device according to claim 1, wherein the bonding part further contains silicon.

4. The electronic device according to claim 3, wherein the bonding part is constituted by a silicon film; a metal film containing at least one kind selected from the group consisting of iron, cobalt, nickel, ruthenium, rhodium, palladium, osmium, iridium and platinum; and a silicon film in this order.

5. The electronic device according to claim 1, wherein both of the substrate and the sealing substrate are gas barrier films.

6. The electronic device according to claim 1, wherein the gas barrier film comprises a layer formed by modifying a polysilazane compound.

7. A method for manufacturing an electronic device, comprising the steps of:
preparing an electronic element main body formed on a substrate;
forming bonding margins each containing at least one kind selected from the group consisting of iron, cobalt, nickel, ruthenium, rhodium, palladium, osmium, iridium and platinum for bonding the substrate and the sealing material for sealing the electronic element main body on the surface of the substrate and the surface of the sealing substrate, respectively; and
bringing the bonding margins into contact and forming a bonding part by room-temperature bonding,
wherein at least one of the substrate and the sealing substrate is a gas barrier film.

8. The method for manufacturing an electronic device according to claim 7, wherein the bonding margins are formed by sputtering.

9. The method for manufacturing an electronic device according to claim 7, wherein the surface center line average roughnesses (Ra) of the surface of the substrate and the surface of the sealing substrate before forming the bonding margin are each 5 nm or less.

10. The electronic device according to claim 2, wherein the bonding part further contains silicon.

11. The electronic device according to claim 2, wherein both of the substrate and the sealing substrate are gas barrier films.

12. The electronic device according to claim 2, wherein the gas barrier film comprises a layer formed by modifying a polysilazane compound.

13. The electronic device according to claim 3, wherein both of the substrate and the sealing substrate are gas barrier films.

14. The electronic device according to claim 3, wherein the gas barrier film comprises a layer formed by modifying a polysilazane compound.

15. The electronic device according to claim 4, wherein both of the substrate and the sealing substrate are gas barrier films.

16. The electronic device according to claim 4, wherein the gas barrier film comprises a layer formed by modifying a polysilazane compound.

17. The electronic device according to claim 5, wherein the gas barrier film comprises a layer formed by modifying a polysilazane compound.

18. The method for manufacturing an electronic device according to claim 8, wherein the surface center line average roughnesses (Ra) of the surface of the substrate and the surface of the sealing substrate before forming the bonding margin are each 5 nm or less.
